(19) United States
(12) Patent Application Publication
(10) Pub. No.: US 2023/0058646 A1
(43) Pub. Date: Feb. 23, 2023

(54) CLEANING DEVICES AND CLEANING METHODS

(71) Applicant: CHANGXIN MEMORY TECHNOLOGIES, INC., Hefei City, Anhui (CN)

(72) Inventor: Buxiang CHEN, Hefei City, Anhui (CN)

(21) Appl. No.: 17/428,047

(22) PCT Filed: Feb. 8, 2021
(86) PCT No.: PCT/CN2021/076092

§ 371 Date: Aug. 3, 2021

(30) Foreign Application Priority Data
Feb. 24, 2020 (CN) 202010112641.1

(51) Int. Cl. B08B 1/00; B08B 1/04; B08B 13/00; B08B 3/00

(52) U.S. Cl. CPC B08B 1/002; B08B 1/04; B08B 3/00; B08B 13/00

(57) ABSTRACT

The present application relates to the field of semiconductors and discloses a cleaning device and a cleaning method. The cleaning device comprises a bearing mechanism for supporting an object to be cleaned in a preset direction, and a cleaning mechanism for cleaning the object to be cleaned, the cleaning mechanism comprising a base and a first cleaning member detachably disposed on the base. The first cleaning member comprises a housing for detachably connecting with the base and a first brush head portion disposed on the housing, an accommodating space being formed and surrounded by the housing and the first brush head portion. A second cleaning member is further disposed on the base, the second cleaning member being accommodated in the accommodating space.

### CROSS-REFERENCE TO RELATED APPLICATIONS

The present application claims the priority to a Chinese Patent Application 202010112641.1, titled “CLEANING DEVICES AND CLEANING METHODS”, filed on Feb. 24, 2020, which is incorporated herein by reference in its entirety.

### TECHNICAL FIELD

The present application relates to the field of semiconductors, and in particular, to a cleaning device and a cleaning method.

### BACKGROUND OF THE PRESENT INVENTION

In the semiconductor production process, there are usually many particles attached to the surface of wafers before the wafer are cleaned. Once these wafers with particles are passed to the exposure machine, the particles will form focal spots and/or chuck spots on the surface of the wafers, resulting in abnormal patterns and reduced yield. Therefore, before the wafers are passed to the exposure machine, they usually need to be cleaned by a backside surface treatment (BST) device to remove some particles from the surface of the wafers, thereby reducing the focal spots and/or chuck spots and further improving the product yield.

However, it was found by the inventor(s) of the present application that, at present, in the BST device, the wafers are usually cleaned by a cleaning member, for example, a brush head. Once the cleaning member works abnormally, the wafers may be damaged. In this case, it is usually necessary to replace the cleaning member with a new one, which will cause the long-term shutdown of the device and affect the productivity.

### SUMMARY OF THE PRESENT INVENTION

Some implementations of the present application provide a cleaning device, comprising a bearing mechanism for supporting an object to be cleaned in a preset direction, and a cleaning mechanism for cleaning the object to be cleaned, the cleaning mechanism comprising a base and a first cleaning member detachably disposed on the base. The first cleaning member comprises a housing for detachably connecting with the base and a first brush head portion disposed on the housing, an accommodating space being formed and surrounded by the housing and the first brush head portion. A second cleaning member is further disposed on the base, the second cleaning member being accommodated in the accommodating space.

Some implementations of the present application further provide a cleaning method, which is applied to the cleaning device described above, comprising: controlling, when the first cleaning member is removed, the bearing mechanism and the second cleaning member to approach each other in the preset direction by a first preset distance, the first preset distance being the difference in height between the first cleaning member and the second cleaning member in the preset direction.

In some implementations of the present application, the bearing mechanism is provided to support the object to be cleaned, the first cleaning member is detachably disposed on the base, the accommodating space is formed between the first brush head portion and the housing of the first cleaning member, and the second cleaning member is accommodated in the accommodation space. When the first cleaning member works abnormally, the first cleaning member can be removed to expose the second cleaning member accommodated in the accommodating space, to continue cleaning the object to be cleaned by the second cleaning member. This ensures the continuous working of the cleaning device, and avoids the long-term shutdown of the device due to the failure of the cleaning member. Therefore, the productivity is ensured.

### BRIEF DESCRIPTION OF THE DRAWINGS

One or more embodiments will be exemplified by pictures in the corresponding drawings. These exemplified descriptions do not constitute any limitation to the embodiments. Elements with the same reference numerals in the drawings are represented as similar. Unless otherwise stated, the drawings are not necessarily drawn to scale.

FIG. 1 is a schematic structure diagram of a cleaning device according to an implementation of the present application;

FIG. 2 is a schematic structure diagram of a cleaning device according to another implementation of the present application;

FIG. 3 is a schematic structure diagram of a cleaning device according to still another implementation of the present application;

FIG. 4 is a schematic structure diagram of a cleaning device according to yet another implementation of the present application; and

FIG. 5 is a schematic structure diagram of a cleaning device according to further another implementation of the present application.

### DETAILED DESCRIPTION OF THE PRESENT INVENTION

To make the objectives, technical solutions and advantages of the present application clearer, some implementations of the present application will be described below in detail with reference to the accompanying drawings. However, it may be understood by a person of ordinary skill in the art that, in some implementations of the present application, many technical details are provided for the better understanding of the present application. However, the technical solutions sought to be protected by the present application can be implemented, even without these technical details and various changes and modifications based on the following implementations.

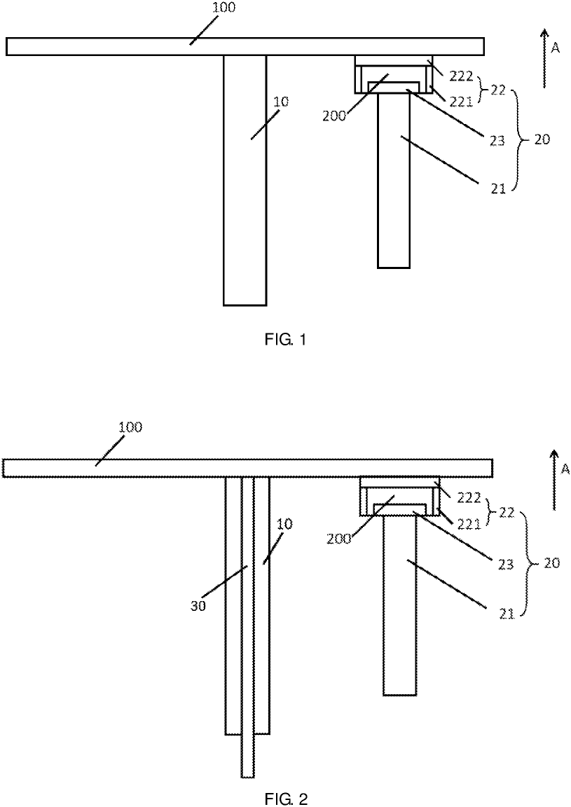

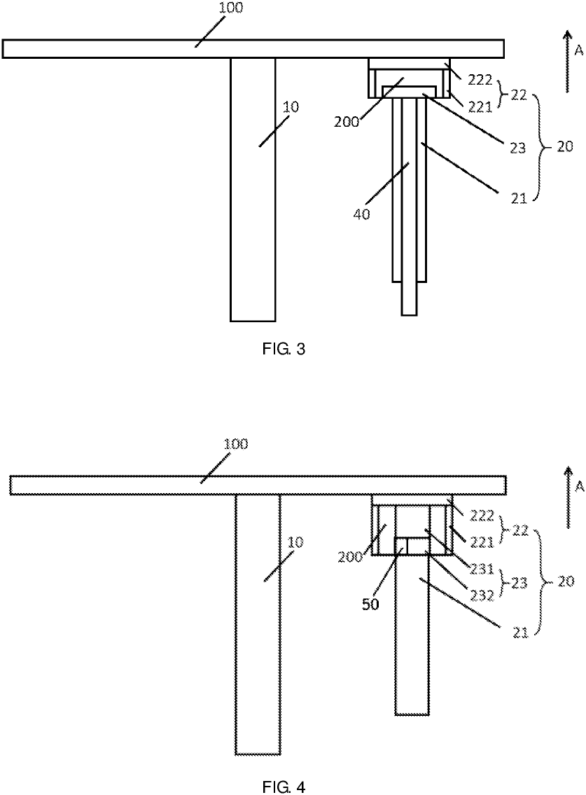

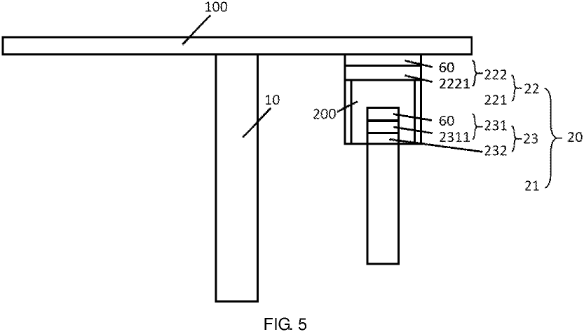

An implementation of the present application relates to a cleaning device, as shown in FIG. 1, comprising a bearing mechanism 10 and a cleaning mechanism 20. The bearing mechanism 10 is used for supporting an object to be cleaned 100 in a preset direction (direction A in FIG. 1), and the cleaning mechanism 20 is used for cleaning the object to be cleaned 100. The cleaning mechanism 20 comprises a base 21 and a first cleaning member 22 detachably disposed on the base 21. The first cleaning member 22 comprises a housing 221 for detachably connecting with the base 21, and a first brush head portion 222 disposed on the housing 221, an accommodating space 200 being surrounded by the housing 221 and the first brush head portion 222. A second cleaning member 23 is accommodated in the accommodating space 200 and the second cleaning member 23 is disposed on the base 21.

In the cleaning device in this implementation, the first cleaning member 22 is detachably disposed on the base 21, the accommodating space 200 is formed in the first cleaning member 22, and the second cleaning member 23 is accommodated in the accommodation space 200. When the first cleaning member 22 works abnormally and fails to clean the object to be cleaned, for example the wafer, the first cleaning member 22 can be removed to expose the second cleaning member 23, to continue cleaning the object to be cleaned by the second cleaning member 23. It is unnecessary to reassemble a cleaning member. This avoids the long-term shutdown of the device due to the failure of the cleaning member. Therefore, the productivity is ensured.

Another implementation of the present application relates to a cleaning device. This implementation is substantially the same as the previous implementation, both comprising a bearing mechanism 10, a cleaning mechanism 20, a base 21, a first cleaning member 22, and a second cleaning member 23, with the main difference that, as shown in FIG. 2, in this implementation of the present application, the cleaning device further comprises a first moving component 30.

In some implementations, the bearing mechanism 10 is disposed on the first moving component 30 and drivable by the first moving component 30 to move in the preset direction.

It should be noted that driving the bearing mechanism 10 by the first moving component 30 to move in the preset direction is a specific example of this implementation and does not constitute any limitation to the present application. In other implementations of the present application, the bearing mechanism 10 may be driven by other structures to move in the preset direction. It may be determined flexibly according to actual needs.

In some implementations, the first moving component 30 is a rotatable screw rod, the bearing mechanism 10 is sleeved on the first moving component 30, and the inner wall of the bearing mechanism 10 adjacent to the first moving component 30 is fitted with the first moving component 30. When the first moving component 30 rotates, it drives the bearing mechanism 10 to move in the preset direction. It may be understood that the foregoing description is an example of implementable structures of the first moving component 30 and the bearing mechanism 10 and does not constitute any limitation to the present application. In other implementations of the present application, other structures may be used. For example, the first moving component 30 is a lifting rod, and the bearing mechanism 10 is fixed on the first moving component 30. The structures will not be exhausted here and may be determined flexibly according to actual needs.

In addition, in some implementations, the movable distance of the bearing mechanism 10 is greater than or equal to a first preset distance, the first preset distance being the difference in height between the first cleaning member 22 and the second cleaning member 23 in the preset direction.

This implementation retains all the technical effects of the previous implementation, and meanwhile, by setting the first moving component to drive the bearing mechanism 10 to move in the preset direction, the bearing mechanism 10 may be moved close to or away from the cleaning mechanism 20, which facilitates the detachment of the first cleaning member 22 and also improves the cleaning effect of the second cleaning member 23.

Still another implementation of the present application relates to a cleaning device. This implementation is substantially the same as the previous implementation, both comprising a bearing mechanism 10, a cleaning mechanism 20, a base 21, a first cleaning member 22, and a second cleaning member 23, with the main difference that, in this implementation, the cleaning device further comprises a second moving component 40.

In some implementations, the second cleaning member 23 is disposed on the second moving component 40 and drivable by the second moving component 40 to move in the preset direction.

It should be noted that driving the second cleaning member 23 by the second moving component 40 to move in the preset direction is a specific example of this implementation and does not constitute any limitation to the present application. In other implementations of the present application, the second cleaning member 23 may be driven by other structures to move in the preset direction. It may be determined flexibly according to actual needs.

In some implementations, the second moving component 40 is a rotatable screw rod, the second cleaning member 23 is sleeved on the second moving component 40, and the inner wall of the second cleaning member 23 adjacent to the second moving component 40 is fitted with the second moving component 40. When the second moving component 40 rotates, it drives the second cleaning member 23 to move in the preset direction. It may be understood that the foregoing description is an example of implementable structures of the second moving component 40 and the second cleaning member 23 and does not constitute any limitation to the present application. In other implementations of the present application, other structures may be used. For example, the second moving component 40 is a lifting rod, and the second cleaning member 23 is fixed on the second moving component 40. The structures will not be exhausted here and may be determined flexibly according to actual needs.

In addition, the movable distance of the second cleaning member 23 is greater than or equal to a first preset distance, the first preset distance being the difference in height between the first cleaning member 22 and the second cleaning member 23 in the preset direction.

This implementation retains all the technical effects of the previous implementation, and meanwhile, by setting the second moving component 40 to drive the second cleaning member 23 to move in the preset direction, the second cleaning member 23 may be moved close to or away from the bearing mechanism 10, which improves the cleaning effect of the second cleaning member 23.

Yet another implementation of the present application relates to a cleaning device. This implementation is substantially the same as the previous implementation, both comprising a bearing mechanism 10, a cleaning mechanism 20, a base 21, a first cleaning member 22, and a second cleaning member 23, with the main difference that, as shown in FIG. 4, in this implementation, the second cleaning member 23 comprises a second brush head portion 231 for cleaning the object to be cleaned 100 and an elastic portion 232 connected to the bottom of the second brush head portion 231. When the first cleaning member 22 is detached, the elastic portion 232 lifts the second brush head portion 231 to move in the preset direction by a first preset distance, the first preset distance being the difference in height between the first cleaning member 22 and the second cleaning member 23 in the preset direction.

In some implementations, the first brush head portion 222 presses the top of the second brush head portion 231. When the first cleaning member 22 is detached, the elastic portion 232 is released so that the second brush head portion 231 is lifted to move in the preset direction.

This implementation retains all the technical effects of the previous implementation, and meanwhile, with the arrangement of the elastic portion 232 to lift the second brush head portion 231 to move in the preset direction by the first preset distance, the cleaning effect of the object to be cleaned 100 by the second brush head portion 231 is ensured. In addition, when the first brush head portion 222 in this implementation is detached, the elastic portion 232 lifts the second brush head portion 231 to move in the preset direction by the first preset distance, and there is no relative movement between the bearing mechanism 10 and the cleaning mechanism 20. When there are multiple first brush head portions 222 in the cleaning mechanism 20, the replacement or detachment of some of the first brush head portions 222 will not affect the normal operation of other first brush head portions 222, which can effectively reduce the frequency of replacement of the first brush head portion 222. In this way, the frequency of replacement or detachment can be effectively reduced while avoiding waste, and the efficiency of replacement or detachment can be improved.

In some implementations, the cleaning device further comprises a limiting member 50 disposed on the elastic portion 232; and the limiting member 50 is used for limiting the distance that the elastic portion 232 drives the second brush head portion 231 to move in the preset direction. The arrangement of the limiting member 50 on the elastic portion 232 can prevent the elastic portion 232 from pressing the second brush head portion 231 on the object to be cleaned 100 to result in the position offset of the object to be cleaned 100, thereby ensuring the cleaning quality.

Further another implementation of the present application relates to a cleaning device. This implementation is substantially the same as the previous implementation, both comprising a bearing mechanism 10, a cleaning mechanism 20, a base 21, a first cleaning member 22, and a second cleaning member 23, with the main difference being that, in this implementation, the first brush head portion 222 comprises a first baseplate 2221 disposed on the housing 221 and bristles 60 disposed on the first baseplate 2221, and the second brush head portion 231 comprises a second baseplate 2311 and bristles 60 disposed on the second baseplate 2311. The second baseplate 2311 is a foldable baseplate.

This implementation retains all the technical effects of the previous implementation, and meanwhile, setting the second baseplate 2311 to be a foldable baseplate can ensure that, after the first cleaning member 22 is removed, when the object to be cleaned 100 is cleaned by the second cleaning member 23, the cleaning area of the second cleaning member 23 can be effectively increased, thereby improving the cleaning efficiency.

In some implementations, the distribution area of the bristles on the second baseplate 2311 after the second baseplate 2311 is unfolded is equal to the distribution area of the bristles on the first baseplate 2221. Setting the distribution area of the bristles on the second baseplate 2311 after it is unfolded to be equal to the distribution area of the bristles on the first baseplate 2221 can ensure the same cleaning area of the first cleaning member 22 and the second cleaning member 23, so that it is unnecessary to change other parts of the cleaning device, for example, the cleaning speed, the cleaning cycle, etc., thereby ensuring the cleaning efficiency of the cleaning device.

Another implementation of the present application relates to a cleaning method, which is applied to the cleaning device described in the above implementations, comprising: controlling, when the first cleaning member 22 is removed, the bearing mechanism 10 and the second cleaning member 23 to approach each other in the preset direction by a first preset distance, the first preset distance being the difference in height between the first cleaning member 22 and the second cleaning member 23 in the preset direction.

Since the cleaning method in this implementation is applied to the cleaning device described in the above implementations, it has the same technical effects as those in the above implementations, which will not be repeated here.

It may be understood by a person of ordinary skill in the art that the above-mentioned implementations are specific embodiments for realizing the present application, and in actual applications, various changes may be made to the form and details without departing from the spirit and scope of the present application.

1. A cleaning device, comprising:
a bearing mechanism for supporting an object to be cleaned in a preset direction, and a cleaning mechanism for cleaning the object to be cleaned, the cleaning mechanism comprising a base and a first cleaning member detachably disposed on the base;
the first cleaning member comprises a housing for detachably connecting with the base and a first brush head portion disposed on the housing, an accommodating space being formed and surrounded by the housing and the first brush head portion; and
a second cleaning member is further disposed on the base, the second cleaning member being accommodated in the accommodating space.

2. The device according to claim 1, further comprising a first moving component, the bearing mechanism being disposed on the first moving component and drivable by the first moving component to move in the preset direction.

3. The device according to claim 2, wherein the movable distance of the bearing mechanism is greater than or equal to a first preset distance, the first preset distance being the difference in height between the first cleaning member and the second cleaning member in the preset direction.

4. The device according to claim 1, further comprising a second moving component, the cleaning mechanism being disposed on the second moving component and drivable by the second moving component to move in the preset direction.

5. The device according to claim 4, wherein the movable distance of the second cleaning member is greater than or equal to a first preset distance, the first preset distance being the difference in height between the first cleaning member and the second cleaning member in the preset direction.

6. The device according to claim 1, wherein the second cleaning member comprises a second brush head portion for cleaning the object to be cleaned and an elastic portion connected to the bottom of the second brush head portion, the first brush head portion pressing top of the brush head portion; and
when the first cleaning member is detached, the elastic portion lifts the second brush head portion to move in the preset direction by a first preset distance, the first preset distance being the difference in height between the first cleaning member and the second cleaning member in the preset direction.

7. The device according to claim 6, further comprising a limiting member disposed on the elastic portion; and
the limiting member is used for limiting the distance that the elastic portion drives the brush head portion to move in the preset direction.

8. The device according to claim 1, wherein the first brush head portion comprises a first baseplate disposed on the housing and bristles disposed on the first baseplate, and the second cleaning member comprises a second baseplate and bristles disposed on the second baseplate; and
the second baseplate is a foldable baseplate.

9. The device according to claim 8, wherein the distribution area of the bristles on the second baseplate after the second baseplate is unfolded is equal to the distribution area of the bristles on the first baseplate.

10. A cleaning method, which is applied to the cleaning device according to claim 1, comprising:
controlling, when the first cleaning member is removed, the bearing mechanism and the second cleaning member to approach each other in the preset direction by a first preset distance, the first preset distance being the difference in height between the first cleaning member and the second cleaning member in the preset direction.
